(19) United States
(12) Patent Application Publication
(10) Pub. No.: US 2024/0355918 A1
(43) Pub. Date: Oct. 24, 2024

(54) HETEROEPITAXIAL SEMICONDUCTOR DEVICES WITH ENHANCED THERMAL DISSIPATION

(71) Applicant: Woflspeed, Inc., Durham, NC (US)

(72) Inventors: Christer Hallin, Hillsborough, NC (US); Matt King, Wake Forest, NC (US); Thomas Kuhr, Durham, NC (US)

(21) Appl. No.: 18/137,797

(22) Filed: Apr. 21, 2023

(51) Int. Cl. H01L 29/778; H01L 29/08; H01L 29/16; H01L 29/20; H01L 29/66

(52) U.S. Cl. CPC H01L 29/7786; H01L 29/0847; H01L 29/1608; H01L 29/2003; H01L 29/66462

(57) ABSTRACT

A method of forming a semiconductor device structure includes patterning a surface of a semiconductor substrate, wherein the semiconductor substrate comprises a material having a thermal conductivity greater than about 50 W/m-K. The method further includes conformally forming a heteroepitaxial layer structure on the surface of the semiconductor substrate, and forming a semiconductor device in the heteroepitaxial layer structure. A semiconductor device structure according to some embodiments includes semiconductor substrate having a patterned surface. The semiconductor substrate is formed of a material having a thermal conductivity greater than about 50 W/m-K. The device structure includes a heteroepitaxial layer structure conformally formed on the patterned surface of the semiconductor substrate, and at least one metal contact on the heteroepitaxial layer structure.

### TECHNICAL FIELD

The present disclosure relates to a semiconductor devices, and in particular to semiconductor devices formed on heteroepitaxial structures.

### BACKGROUND

Semiconductor devices, such as high electron mobility transistors (HEMTs), metal oxide field effect transistors (MOSFETs), metal semiconductor field effect transistors (MESFETS), junction field effect transistors (JFETs) and other devices may be formed on or in heteroepitaxial semiconductor structures.

A simplified cross-section of an exemplary GaN based high electron mobility transistor (HEMT) 100 having a silicon carbide substrate is shown in FIG. 1. The HEMT 100 is formed in a semiconductor epitaxial structure 115 comprising a plurality of Group Ill nitride material epitaxial layers 116, 118 on a substrate 102. In particular, the HEMT 100 is formed in an aluminum gallium nitride (AlGaN)/gallium nitride (GaN) material system, and the substrate 102 is formed of silicon carbide (SIC). The substrate 102 is a semi-insulating substrate formed of a 4H polytype of SiC. Optional SiC polytypes include 3C, 6H, and 15R polytypes. Alternative materials for the substrate 102 may include sapphire (Al₂O₃), aluminum nitride (AIN), AIGaN, GaN, silicon (Si), gallium arsenide (GaAs), zinc oxide (ZnO), and indium phosphide (InP). The substrate 102 is generally between 300 micrometers and 1000 micrometers thick.

To facilitate heteroepitaxial growth crystal on the substrate 102, a nucleation layer (not shown) may be formed on a surface of the substrate 102 to provide an appropriate crystal structure transition between the SiC of the substrate 102 and the various epitaxial layers that are to be formed on the substrate 102. “Heteroepitaxial growth” or “heteroepitaxy” refers to the crystal growth of a layer of a material on a substrate having a different material composition from the epitaxially grown layer. Thus, for example, growth of GaN or GaN-based crystal layers on a SiC substrate is referred to as heteroepitaxial growth. In contrast, epitaxial growth on a substrate of a layer having the same material composition as the substrate, such as epitaxial growth of a layer of SiC on a SiC substrate, is referred to as “homoepitaxy.”

The nucleation layer may be a single layer or a series of layers. The nucleation layer is generally between 10 nm and 60 nm thick. The epitaxial structure 115 may include additionally layers or sub-layers, such as cap layers, buffer layers, and other layers.

A channel layer 116 is formed on the nucleation layer. The channel layer 116 is formed by one or more epitaxial layers. For this example, the channel layer 116 may be GaN. However, the channel layer 116 may more generally be a Group Ill nitride such as GaN, AlXGa1-XN where 0≤X<1, indium gallium nitride (InGaN), aluminum indium gallium nitride (AllnGaN), or the like. The channel layer 116 may be undoped, or at least unintentionally doped, and may be grown to a thickness of greater than about 2 nm. In certain embodiments, the channel layer 116 may employ a multi-layer structure, such as a superlattice or alternating layers of different Group III-nitrides, such as GaN, AlGaN, or the like.

A barrier layer 118 is formed on the channel layer 116. The barrier layer 118 may have a bandgap that is greater than the bandgap of the underlying channel layer 116. Further, the barrier layer 118 may have a smaller electron affinity than the channel layer 116. In this illustrated embodiment, the barrier layer 118 is AlGaN. However, the barrier layer 118 may include AlGaN, AllnGaN, AIN, or various combinations of these layers. The barrier layer 118 is generally between 2 nm and 40 nm thick; however, the barrier layer 118 should not be so thick as to cause cracking or substantial defect formation therein. The barrier layer 118 may be either undoped, or at least unintentionally doped, or doped with an n-type dopant to a concentration less than about 1E19 cm⁻³. Notably, together, the channel layer 116 and the barrier layer 118 form a semiconductor body of the HEMT 100.

As shown in FIG. 1, a surface dielectric layer 126 is formed on a surface of the barrier layer 118 opposite the channel layer 116 and is etched using known etching techniques to the shape shown. In this embodiment, the surface dielectric layer 126 is silicon nitride (SIN). However, the surface dielectric layer 126 may be formed of another suitable dielectric such as, for example, silicon dioxide (SiO2), aluminum silicon nitride (AISIN), silicon oxynitride (SiON), or the like. It will be understood that the terms “SixNy,” “SIN,” and “silicon nitride” are used herein interchangeably to refer to both stoichiometric and non-stoichiometric SiN. Other materials that may be used for the surface dielectric layer 126 include, for example, magnesium oxide, scandium oxide, aluminum oxide, and/or aluminum oxynitride. Furthermore, the surface dielectric layer 126 may be a single layer or may include multiple layers of uniform or non-uniform composition. The material of the surface dielectric layer 126 should be capable of withstanding relatively high temperatures, and should allow at least a portion to be removed without significantly damaging the underlying barrier layer 118.

In general, the surface dielectric layer 126 may provide a relatively high breakdown field strength and a relatively low interface trap density at the interface with an underlying Group III nitride layer such as the barrier layer 118. The surface dielectric layer 126 may have a high etch selectivity with respect to the material of the barrier layer 118, and may not be reactive to the material of the barrier layer 118. Moreover, the surface dielectric layer 126 may have a relatively low level of impurities therein. For example, the surface dielectric layer 126 may have a relatively low level of hydrogen and other impurities, including oxygen, carbon, fluorine, and chlorine. The surface dielectric layer 126 is generally between 80 nm and 200 nm thick.

As illustrated, the surface dielectric layer 126 is etched to expose surface portions 122A, 122B, 122C of the barrier layer 118. The area beneath the surface portion 122A corresponds to the drain region, and the area beneath the surface portion 122B corresponds to the source region. The areas beneath the surface portions 122A and 122B, which correspond to the drain and source regions, are subjected to a “shallow implant” of dopant ions to form respective shallow implant regions 124. The shallow implant regions 124 extend through the barrier layer 118 and at least partially into the channel layer 116. As such, the ions for the doping material come to rest in both the barrier layer 118 and at least the upper portion of the channel layer 116 beneath the surface portions 122A and 122B.

As used herein, the term “shallow implant” means that the implants are made directly into the barrier layer 118 with no substantive capping or protection layer over the surface portions 122A and 122B of the barrier layer 118 during implantation. The implanted ions of the doping material may be implanted such that a peak of the implant profile is located just below the interface between the channel layer 116 and the barrier layer 118 where a two-dimensional electron gas (2-DEG) plane is formed during operation and in which electron conductivity is modulated. While the doping concentrations may vary based on desired performance parameters, first exemplary doping conditions may provide shallow implant regions 124 with a peak doping concentration of 1×10¹⁸ cm⁻³ or greater and a straggle of 50 nanometers (nm) or less. For example, in some embodiments, the dose and energy of the implants may be selected to provide a peak doping concentration of about 5×10¹⁹ cm⁻³ and a straggle of about 30 nm. In order to form n-type shallow implant regions 124 in a nitride-based barrier layer 118, the implanted ions may include Si ions, sulfur ions, oxygen ions, or a combination thereof.

On the surface portion 122A, a drain contact 114 is formed. The drain contact 115 is an ohmic contact that cooperates with the shallow implant region 124 residing beneath the surface portion 122A to provide a low resistance connection to the drain region of the HEMT 100. Similarly, on the surface portion 122B, a source contact 110 is formed. The source contact 110 is an ohmic contact that cooperates with the shallow implant region 124 residing beneath the surface portion 122B to provide a low resistance connection to the source region of the HEMT 100. The source and drain regions connect with the opposite sides of the 2-DEG plane, which is just below the junction of the channel layer 116 and barrier layer 118.

As noted above, the surface dielectric layer 126 is also etched to expose the surface portion 122C of the barrier layer 118. The surface portion 122C resides between the surface portions 122A and 122B and corresponds to a gate region of the HEMT 100. A gate contact 112 is formed with one or more metallic layers over the surface portion 122C of the barrier layer 118.

Referring still to FIG. 1, a portion of the gate contact 112 may be formed directly on the barrier layer 118, which itself may be formed from multiple epitaxial layers. Typically, an opening is etched through the surface dielectric layer 126 to expose the surface portion 122C. As illustrated, the gate contact 112 may have a portion that resides within the opening in contact with the surface portion 122C as well as portions that reside along the sidewalls of the opening and on an upper surface of the surface dielectric layer 126 on either side of the opening.

The gate contact 112 forms a non-ohmic contact with the barrier layer 118, and in particular may form a Schottky contact to the barrier layer 118.

A second dielectric layer 128 is formed over the surface dielectric layer 126 and the gate contact 112. A drain metallization layer 132 contacts the drain contact 115 through the second dielectric layer 128, and a source metallization layer 134 contacts the source contact 110 through the second dielectric layer 128. A field plate 122 is electrically connected to the source contact 110 via the source metallization layer 134 and extends over the gate contact 112. The field plate 122 reduces the negative impact of nearby electromagnetic fields on the gate contact 112 of the HEMT 100. The source metallization 134 connects to a backside source electrode 123 via a backside via 118 through the substrate 102.

### SUMMARY

A method of forming a semiconductor device structure includes patterning a surface of a semiconductor substrate, wherein the semiconductor substrate comprises a material having a thermal conductivity greater than about 50 W/m-K. The method further includes conformally forming a heteroepitaxial layer structure on the surface of the semiconductor substrate, and forming a semiconductor device in the heteroepitaxial layer structure.

In some embodiments, patterning the surface of the semiconductor substrate comprises etching a plurality of features into the semiconductor substrate.

The plurality of features may comprise trenches, pits, ridges and/or pedestals in the surface of the semiconductor substrate.

The presence of the features in the surface of the semiconductor substrate causes a surface area of an interface between the heteroepitaxial layer structure and the semiconductor substrate to be larger than it would be absent the features in the surface of the semiconductor substrate.

In some embodiments, a total surface area of the interface between the semiconductor substrate and the heteroepitaxial layer structure is at least about 50% greater than a total surface area of the interface would be without the features.

In some embodiments, the plurality of features have rectangular cross-sections. In some embodiments, the plurality of features have U-shaped or V-shaped cross-sections.

In some embodiments, the plurality of features comprise trenches, and the trenches extend in a direction corresponding to a direction of a flow of charge carriers during device operation.

The substrate may include silicon carbide, and the heteroepitaxial layer structure may include a gallium nitride based material. The semiconductor substrate may have a thermal conductivity greater than about 100 W/m-K. The semiconductor device may be a high electron mobility transistor.

In some embodiments, patterning the surface of the substrate includes forming an etch mask on the surface of the substrate, forming a plurality of openings in the etch mask, and anisotropically etching the surface of the substrate through the plurality of openings in the etch mask to form a plurality of recessed features in the surface of the substrate. Anisotropically etching the surface of the substrate may be performed using a reactive ion etch.

A semiconductor device structure according to some embodiments includes semiconductor substrate having a patterned surface. The semiconductor substrate is formed of a material having a thermal conductivity greater than about 50 W/m-K. The device structure includes a heteroepitaxial layer structure conformally formed on the patterned surface of the semiconductor substrate, and at least one metal contact on the heteroepitaxial layer structure.

### BRIEF DESCRIPTION OF THE DRAWINGS

FIG. 1 is a simplified cross-section of a conventional high electron mobility transistor (HEMT).

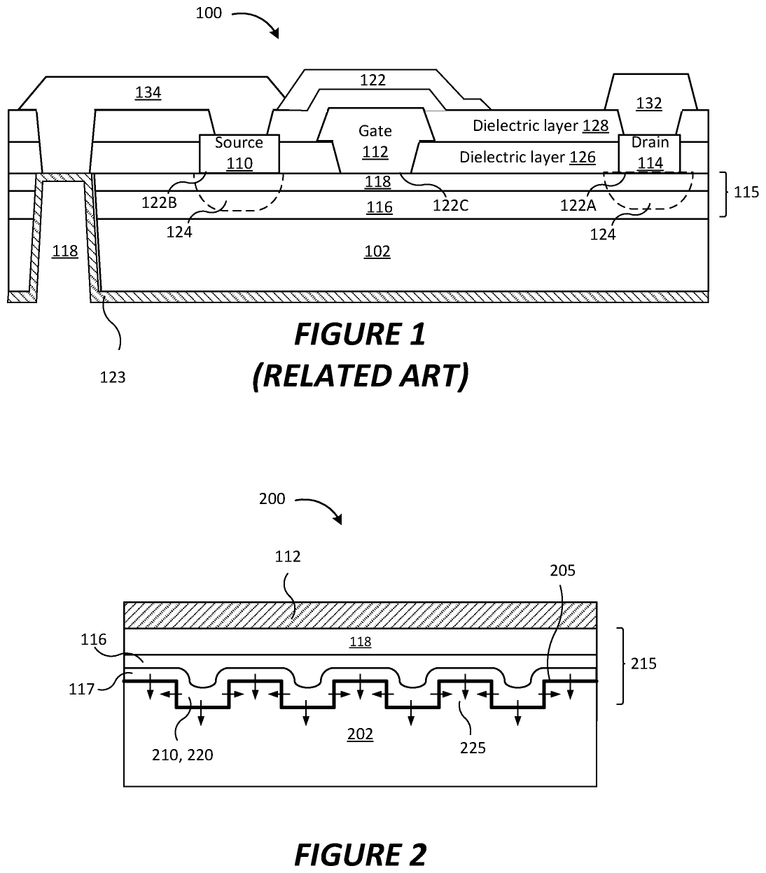

FIG. 2 is a cross-section of a HEMT device structure according to some embodiments.

FIGS. 3A and 3B are plan views of HEMT device structures according to some embodiments.

FIGS. 4A to 4F are cross-sectional views illustrating operations for forming HEMT device structures according to some embodiments.

FIGS. 5A, 5B and 5C are cross-sections of HEMT device structures according to various embodiments.

FIG. 6 is a flowchart illustrating operations for forming HEMT device structures according to some embodiments.

FIGS. 7A-7C are schematic block diagrams of multi-amplifier circuits in which RF power amplifiers incorporating transistor devices according to embodiments may be used.

FIG. 8 is a schematic plan view of a monolithic microwave integrated circuit RF power amplifier according to some embodiments.

FIGS. 9A and 9B are schematic cross-sectional views illustrating two example ways that an RF transistor device according to some embodiments may be packaged to provide RF power amplifiers.

### DETAILED DESCRIPTION OF EMBODIMENTS

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

As noted above, some of the advantages of GaN based HEMT transistors include their ability to operate at high-power levels and high frequencies with high thermal stability. However, one of the main limitations of the performance of GaN based HEMTs is the self-heating effect, in which heat generated by the switching of large currents at high frequencies causes heat to build up in the device. In particular, the self-heating effect causes the channel temperature to increase due to the transfer of energy from the electrons to the crystal lattice. Self-heating can degrade the drain saturation current and transconductance properties of the device, and can cause reliability problems.

Thermal energy generated as a result of self-heating needs to be dissipated efficiently. Even though the SiC substrate itself is an efficient conductor of heat, further improvements are needed in the thermal performance of HEMT devices, especially as the demand for higher driving voltages increases.

Some embodiments are based on a recognition that there is thermal resistance at the interface between the epitaxial structure 115 and the SiC substrate 102 of a GaN based HEMT device. Some embodiments reduce the thermal resistance at the interface between the epitaxial structure by forming a pattern in the surface of the SiC substrate before epitaxially growing the epitaxial structure 115 thereon, so that the interface between the epitaxial structure 115 and the substrate 102 has an increased surface area. As is known in the art, thermal resistance is inversely proportional to the cross-sectional area of the path through which heat flows. Thus, as the cross-sectional area of the path increases, the thermal resistance of the path decreases.

The pattern in the surface of the substrate 102 may be any pattern that increases the surface area of the interface between the substrate 102 and the epitaxial structure 115. For example, the pattern may be a grooved pattern, a pitted pattern, a corrugated pattern, a pedestaled pattern, or the like.

In some embodiments, a pattern is etched in the SiC substrate to a specific depth before the epitaxial structure 115 is grown, effectively increasing the total surface area of the interface between the substrate 102 and the epitaxial structure 115 of the HEMT. For example, in some embodiments, the depth of the pattern may be from less than 0.1 micrometer up to several micrometers, depending on the width of the features in the pattern.

By increasing the total contact area between the HEMT epitaxial structure 115 and the substrate 102, the thermal resistance of heat dissipation from the epitaxial structure 115 to the substrate 102 may be reduced, thereby enabling more efficient removal of heat from the channel region of the HEMT device.

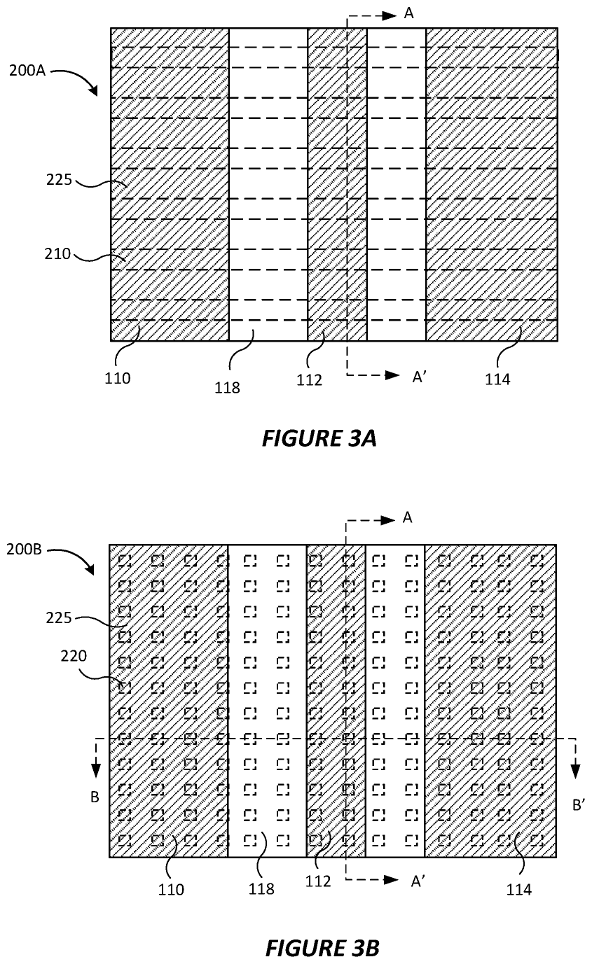

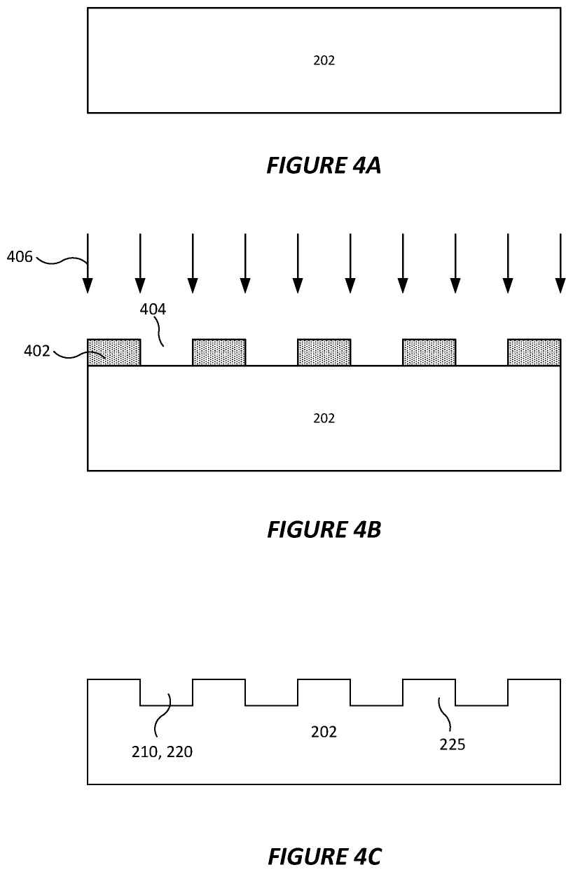

FIG. 2 illustrates a HEMT device structure 200 according to some embodiments. In particular, FIG. 2 is a cross-sectional illustration of the HEMT device structure 200 taken along line A-A′ of FIG. 3A or FIG. 3B, which are plan views of a HEMT device structure according to various embodiments. Referring to FIGS. 2, 3A and 3B, the HEMT device structure 200 includes a high thermal conductivity substrate on which a heteroepitaxial layer structure 215 is formed. The substrate 202 may have a thermal conductivity of greater than about 50 W/m-K, and in some embodiments greater than about 100 W/m-K. For example, the substrate 202 may include silicon carbide, which has a thermal conductivity of about 120 W/m-K. In contrast, non-highly thermally conductive substrate materials such sapphire may have a thermal conductivity of less than about 50 W/m-K.

The heteroepitaxial layer structure 215 includes a nucleation layer 205 on the substrate, a channel layer 116 on the nucleation layer 205 and a barrier layer 118 on the channel layer 116. The nucleation layer 205 may include, for example, aluminum nitride or any other suitable material, and may have a thickness from a few nanometers up to hundreds of nanometers. A metal gate contact 112 is on the barrier layer 118.

As illustrated in FIGS. 2, 3A and 3B, the surface of the substrate 202 on which one or more epitaxial layers are to be formed is patterned to increase the surface area of the interface between the substrate and the epitaxial layers. The increased surface area of the interface may allow the structure to more efficiently dissipate heat from the epitaxial layers into the substrate 202.

In particular, in some embodiments, the substrate 202 to have an arrangement of alternating three dimensional features including trenches 210 or pits 220 that are adjacent raised portions 225. The raised portions 225 may, for example, be ridges or pedestals. The trenches 210 or pits 220 may be formed, for example, by etching the SiC substrate 202, and may have a depth of about 0.1 micrometers to several micrometers and a width of about 0.1 micrometers to several micrometers. In particular embodiments, the trenches 210 or pits 220 may have a depth of about 0.2 micrometers and a width of about 1 micrometer. In some embodiments, the trenches 210 or pits 220 are deeper than they are wide to increase the vertical surface area of the trenches 210 or pits 220 to promote greater heat dissipation.

In some embodiments, the total surface area of the interface between the substrate 202 and the heteroepitaxial layer structure 215 may be at least about 50% greater than the total surface area of the interface would be without the three dimensional features. In some embodiments, the total surface area of the interface between the substrate 202 and the heteroepitaxial layer structure 215 may be at least about 75% greater than the total surface area of the interface would be without the three dimensional features. In some embodiments, the total surface area of the interface between the substrate 202 and the heteroepitaxial layer structure 215 may be at least about 100% greater than the total surface area of the interface would be without the three dimensional features.

The pits 220 may be formed to have different peripheral shapes when viewed from above the substrate. As illustrated in FIG. 3B, the pits 220 may have a square peripheral shape. However, other shapes can be used. For example, the pits 220 may be circular, rectangular or hexagonal in shape.

The nucleation layer 205 encourages epitaxial growth on the sidewalls and bottoms of the trenches 210 or pits 220, as well as on the top surfaces of the raised portions 225.

Etching the SiC substrate 202 may be performed, for example, using an anisotropic dry etch process, such as a reactive ion etch (RIE) process. An anisotropic dry etch process such as RIE may provide precise control of the etch depth.

Following formation of the trenches 210 or pits 220 in the substrate 202, the substrate 202 may be treated with a process to prepare the surface of the substrate 202 for epitaxial growth thereon. Such a process may include an H2 etch, an oxidation/strip process, a wet etch, or other process.

After formation of the trenches 210 or pits 220 and optionally one or more surface treatments of the substrate 202, the nucleation layer 205 may be formed on the substrate 202. As noted above, the nucleation layer 205 may include a layer of AIN, and may be formed on the sidewalls and bottoms of the trenches 210 or pits 220 as well as on the upper surfaces of the raised portions 225. The nucleation layer 205 may be provided to encourage epitaxial growth from the sidewalls and bottoms of the trenches 210 or pits 220 as well as on the upper surfaces of the raised portions 225 in both vertical and lateral directions. Such growth may be contrasted, for example, with pendeo-epitaxial growth techniques which encourage preferential growth from sidewalls of trenches or pillars, or the tops of pillars to promote lateral growth of GaN layers.

Moreover, the use of RIE to etch the trenches 210 or pits 220 may cause the bottom surfaces of the trenches 210 or pits 220 to have a rough morphology, which may further encourage epitaxial growth from the bottom surfaces of the trenches 210 or pits 220.

In fact, during epitaxial growth of the heteroepitaxial layer structure 215, the initial epitaxial growth may be faster or more preferential from the bottom surfaces of the trenches 210 or pits 220 than from the sidewalls of the trenches 210 or pits 220.

After formation of the nucleation layer 205, the heteroepitaxial layer structure 215 may be formed, including the channel layer 116 and the barrier layer 118. The heteroepitaxial layer structure 215 may include other layers such as, for example, a buffer layer 117 between the nucleation layer 205 and the channel layer 116. The buffer layer 117 may be formed of GaN and may be doped, for example, with deep level dopants such as carbon or iron to cause the buffer layer 117 to be semi-insulating.

As explained above, an objective of the formation of the trenches 210 or pits 220 and the raised portions 225 is to increase the surface area of the interface between the heteroepitaxial layer structure 215 and the substrate 202 to facilitate increased heat transfer from the heteroepitaxial layer structure 215 to the substrate 202. As indicated by the arrows in FIG. 2, heat may be transferred from the heteroepitaxial layer structure 215 to the substrate 202 through the sidewalls and bottoms of the trenches 210 or pits 220 as well as through the upper surfaces of the raised portions 225. As further explained above, increasing the surface area of the interface between the heteroepitaxial layer structure 215 and the substrate 202 may reduce the thermal resistance of the heat path from the heteroepitaxial layer structure 215 to the substrate 202.

Moreover, while not wishing to be bound by a particular theory of operation, it is also presently believed that providing a patterned interface between the heteroepitaxial layer structure 215 and the substrate 202, the interface may scatter phonons generated within the active region of the device as charge transit the channel region of the device between the source/drain regions 124 less. Due to lattice mismatch heteroepitaxial interfaces have a high density of boundaries, defects and dislocations, which all interrupt heat transport by phonon scattering. However, there is evidence that interface scattering is more dominant in cross-plane transport compared to in-plane transport. The sidewalls of the trenches 210 or pits 220 constitutes in-plane interfaces, while the bottoms and upper surfaces of 210 or 220, constitutes cross-plane interfaces. Thus, the sidewall interfaces provide less phonon scattering and therefore have a higher thermal conduction than the bottom and upper surfaces of the trenches 210 or pits 220.

heteroepitaxial layer structure heteroepitaxial layer structure heteroepitaxial layer structure heteroepitaxial layer structure heteroepitaxial layer structure heteroepitaxial layer structure heteroepitaxial layer structure heteroepitaxial layer structure heteroepitaxial layer structureReferring to FIG. 3A, in embodiments in which trenches 210 are formed in the substrate 202, in some embodiments, the trenches 210 may extend along a direction corresponding to the direction of current flow within the channel of the HEMT device 200 from the source contact 110 to the drain contact 114. This arrangement may reduce scattering of charge carriers as they transit the channel beneath the gate contact 112 during device operation, and thereby improve the noise characteristics of the device.

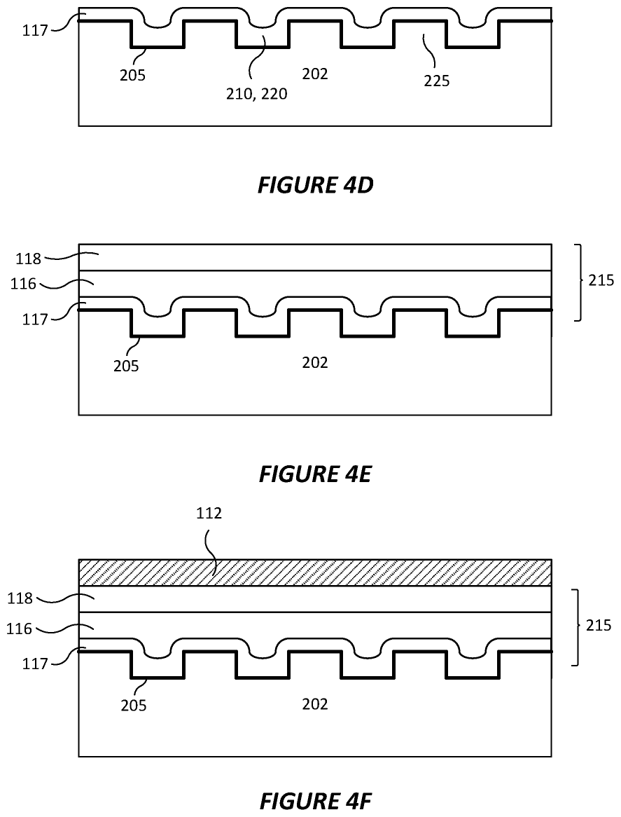

FIGS. 4A to 4F illustrate operations of forming a HEMT structure 200 according to some embodiments. Referring to FIG. 4A, a silicon carbide substrate 202 is provided. The substrate 202 may be formed of silicon carbide having the 2H, 4H, 6H, 3C or 15R polytype, and may be undoped. Referring to FIG. 4B, a mask 402 is formed on the upper surface of substrate 202 and patterned to form openings 404 therein. The substrate 202 is then etched using an anisotropic etch process, such as RIE to form trenches 210 or pits 220 in the substrate 202 beneath the mask openings 404, and raised portions 225 adjacent the trenches 210 or pits 220, as shown in FIG. 4C.

Next, the substrate 202 may optionally be treated with a process to prepare the surface of the substrate 202 for epitaxial growth thereon. Such a process may include an H2 etch, an oxidation/strip process, a wet etch, or other process.

Referring to FIG. 4D, after the trenches 210 or pits 220 have been formed in the substrate 202, a heteroepitaxial layer structure is then formed on the substrate 202. The heteroepitaxial layer structure is formed to be conformal to the patterned surface of the substrate 202. First, a nucleation layer 205 comprising, for example, aluminum nitride (AIN) is conformally formed on the patterned surface of the substrate 202. The nucleation layer 205 is formed on bottom surfaces and sidewalls of the trenches 210 or pits 220, as well as on the raised surfaces 225 adjacent to the trenches 210 or pits 220.

After formation of the nucleation layer 205, the heteroepitaxial layer structure 215 is grown. In particular, a GaN buffer layer 117 may be conformally formed on the nucleation layer 117. The buffer layer 117 may be formed of GaN and may be doped, for example, with deep level dopants such as carbon or iron to cause the buffer layer 117 to be semi-insulating.

As described above, the epitaxial growth from the nucleation layer 117 may proceed preferentially from the bottom surfaces of the trenches 210 or pits 220 compared to the sidewalls of the trenches 210 or pits 220. The buffer layer 117 may completely or partially fill the trenches 210 or pits 220 as shown in FIG. 4D.

Referring to FIG. 4E, the remainder of the heteroepitaxial layer structure 215 is then formed, including at least a channel layer 116 and a buffer layer 118.

Referring to FIG. 4F, metal contacts, including a source and drain contacts 110, 114 (FIG. 3A) and a gate 112.

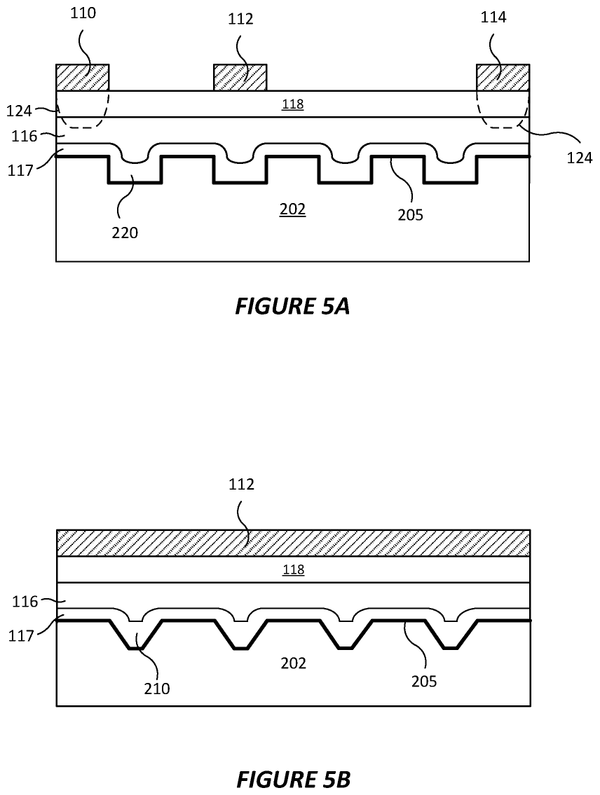

FIG. 5A illustrates a HEMT device structure 200 according to some

embodiments. In particular, FIG. 5A is a simplified cross section of a HEMT device structure 200B taken along line B-B′ of FIG. 3B. FIG. 5B illustrates the pits 220 in the substrate 202 one which a heteroepitaxial layer structure including a GaN buffer layer 117, a channel layer 116 and a barrier layer 118 are formed. A source contact 110, a gate contact 112 and a drain contact 115 are formed on the barrier layer 118. Implanted source/drain regions 124 in the barrier layer 118 and the channel layer 116 facilitate the formation of ohmic contact to the heteroepitaxial layer structure by the source and drain contacts 110, 115.

Although the trenches shown, for example in FIG. 2 have square or rectangular shaped cross-sectional profiles, the trenches 210 may have different cross-sectional profiles. For example, FIG. 5B illustrates an embodiment including trenches 210 in the substrate 202 that have V-shaped cross-sectional profiles, and FIG. 5C illustrates an embodiment including trenches 210 in the substrate 202 that have U-shaped or rounded cross-sectional profiles. In each embodiment, the nucleation layer 205 and heteroepitaxial layers grown thereon are conformal to the shape of the surface of the substrate 202 on which they are grown.

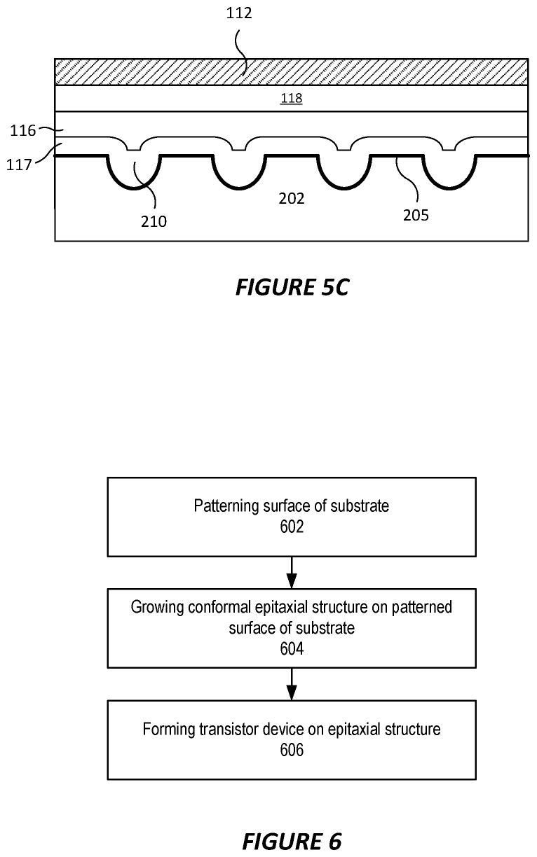

FIG. 6 illustrates operations of forming a semiconductor device structure according to some embodiments. In particular, a substrate, such as a silicon carbide substrate, is patterned or textured at block 602 to form a patterned or textured surface. In particular, the substrate may be patterned or textured by etching a plurality of trenches or pits in the substrate.

At block 604, a heteroepitaxial layer structure is conformally formed on the patterned or textured surface of the substrate. Because the surface of the substrate on which the heteroepitaxial layer structure is conformally formed is patterned or textured, a surface area of the interface between the heteroepitaxial layer structure and the surface of the substrate is increased. The increase surface area of the interface between the heteroepitaxial layer structure and the surface of the substrate may reduce the thermal resistance of a thermal path between the heteroepitaxial layer structure and the substrate.

At block 606, a transistor device, such as a GaN HEMT device, is formed in the epitaxial structure.

Although described above primarily in the context of GaN HEMT devices, structures and/or methods according to the embodiments described herein may be applicable to any type of semiconductor device formed using heteroepitaxy in which it is desirable to reduce the thermal resistance between the heteroepitaxial layer structure and the substrate of the device. Thus, for example, embodiments described herein may be advantageously employed in other types of GaN based devices formed on non-GaN based substrates, including MESFETs, JFETs, MOSFETs and other types of devices.

Transistor devices as described herein may be used in amplifiers that operate in a wide variety of different frequency bands. In some embodiments, the RF power amplifiers incorporating transistor devices as described herein may be configured to operate at frequencies greater than 1 GHz. In other embodiments, the RF power amplifiers may be configured to operate at frequencies greater than 2.5 GHZ. In still other embodiments, the RF power amplifiers may be configured to operate at frequencies greater than 3.1 GHZ. In yet additional embodiments, the RF power amplifiers may be configured to operate at frequencies greater than 5 GHz. In some embodiments, the RF power amplifiers may be configured to operate in at least one of the 2.5-2.7 GHZ, 3.4-4.2 GHZ, 5.1-5.8 GHZ, 12-18 GHz, 18-27 GHZ, 27-40 GHz or 40-75 GHz frequency bands or sub-portions thereof.

Although embodiments of the inventive concepts have been discussed above with respect to HEMT devices, it will be understood that the inventive concepts described herein may be applied to other types of semiconductor devices, such as MOSFETs, DMOS transistors, and/or laterally diffused MOS (LDMOS) transistors.

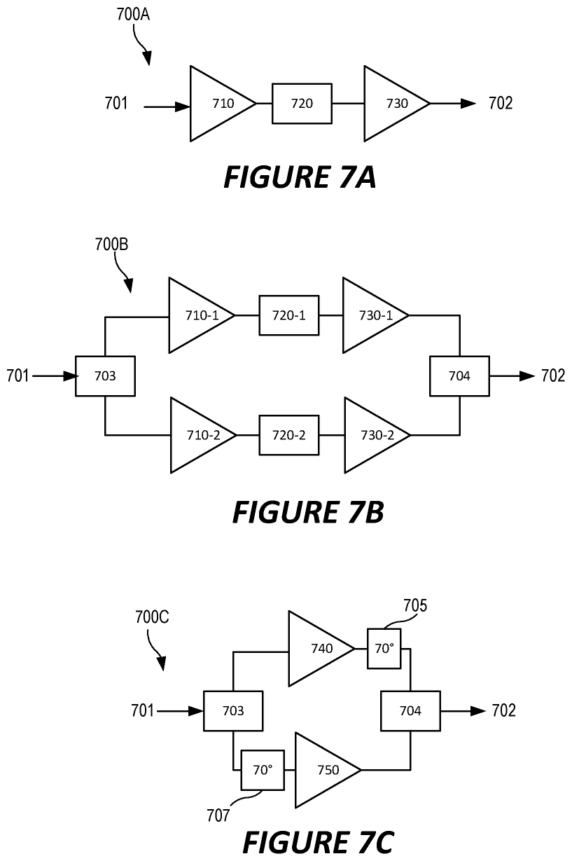

RF power amplifiers incorporating transistor devices described herein can be used in standalone RF power amplifiers and/or in multiple RF power amplifiers. Examples of how the RF power amplifiers according to some embodiments may be used in applications that include multiple amplifiers will be discussed with reference to FIGS. 7A-7C.

Referring to FIG. 7A, an RF power amplifier 700A is schematically illustrated that includes a pre-amplifier 710 and a main amplifier 730 that are electrically connected in series. As shown in FIG. 7A, RF power amplifier 700A includes an RF input 701, the pre-amplifier 710, an inter-stage impedance matching network 720, the main amplifier 730, and an RF output 702. The inter-stage impedance matching network 720 may include, for example, inductors and/or capacitors arranged in any appropriate configuration in order to form a circuit that improves the impedance match between the output of pre-amplifier 710 and the input of main amplifier 730. While not shown in FIG. 7A, RF power amplifier 700A may further include an input matching network that is interposed between RF input 701 and pre-amplifier 710, and/or an output matching network that is interposed between the main amplifier 730 and the RF output 702. The RF power amplifiers according to embodiments may be used to implement either or both of the pre-amplifier 710 and the main amplifier 730.

Referring to FIG. 7B, an RF power amplifier 700B is schematically illustrated that includes an RF input 701, a pair of pre-amplifiers 710-1, 710-2, a pair of inter-stage impedance matching networks 720-1, 720-2, a pair of main amplifiers 730-1, 730-2, and an RF output 702. A splitter 703 and a combiner 704 are also provided. Pre-amplifier 710-1 and main amplifier 730-1 (which are electrically connected in series) are arranged electrically in parallel with pre-amplifier 710-2 and main amplifier 730-2 (which are electrically connected in series). As with the RF power amplifier 700A of FIG. 7A, RF power amplifier 700B may further include an input matching network that is interposed between RF input 701 and pre-amplifiers 710-1, 710-2, and/or an output matching network that is interposed between the main amplifiers 730-1, 730-2 and the RF output 702.

As shown in FIG. 7C, the RF power amplifiers according to some embodiments may also be used to implement Doherty amplifiers. As is known in the art, a Doherty amplifier circuit includes first and second (or more) power-combined amplifiers. The first amplifier is referred to as the “main” or “carrier” amplifier and the second amplifier is referred to as the “peaking” amplifier. The two amplifiers may be biased differently. For example, the main amplifier may comprise a Class AB or a Class B amplifier while the peaking amplifier may be a Class C amplifier in one common Doherty amplifier implementation. The Doherty amplifier may operate more efficiently than balanced amplifiers when operating at power levels that are backed off from saturation. An RF signal input to a Doherty amplifier is split (e.g., using a quadrature coupler), and the outputs of the two amplifiers are combined. The main amplifier is configured to turn on first (i.e., at lower input power levels) and hence only the main amplifier will operate at lower power levels. As the input power level is increased towards saturation, the peaking amplifier turns on and the input RF signal is split between the main and peaking amplifiers.

As shown in FIG. 7C, the Doherty RF power amplifier 700C includes an RF input 701, an input splitter 703, a main amplifier 740, a peaking amplifier 750, an output combiner 704 and an RF output 702. The Doherty RF power amplifier 700C includes a 90° transformer 707 at the input of the peaking amplifier 750 and a 90° transformer 705 at the input of the main amplifier 740, and may optionally include input matching networks and/or an output matching networks (not shown). The main amplifier 740 and/or the peaking amplifier 750 may be implemented using any of the above-described RF power amplifiers according to embodiments.

The RF power amplifiers according to embodiments may be formed as discrete devices, or may be formed as part of a Monolithic Microwave Integrated Circuit (MMIC). A MMIC refers to an integrated circuit that operates on radio and/or microwave frequency signals in which all of the circuitry for a particular function is integrated into a single semiconductor chip. An example MMIC device is a power amplifier that includes associated matching circuits, feed networks and the like that are all implemented on a common substrate. MMIC transistor amplifiers typically include a plurality of unit cell HEMT transistors that are connected in parallel.

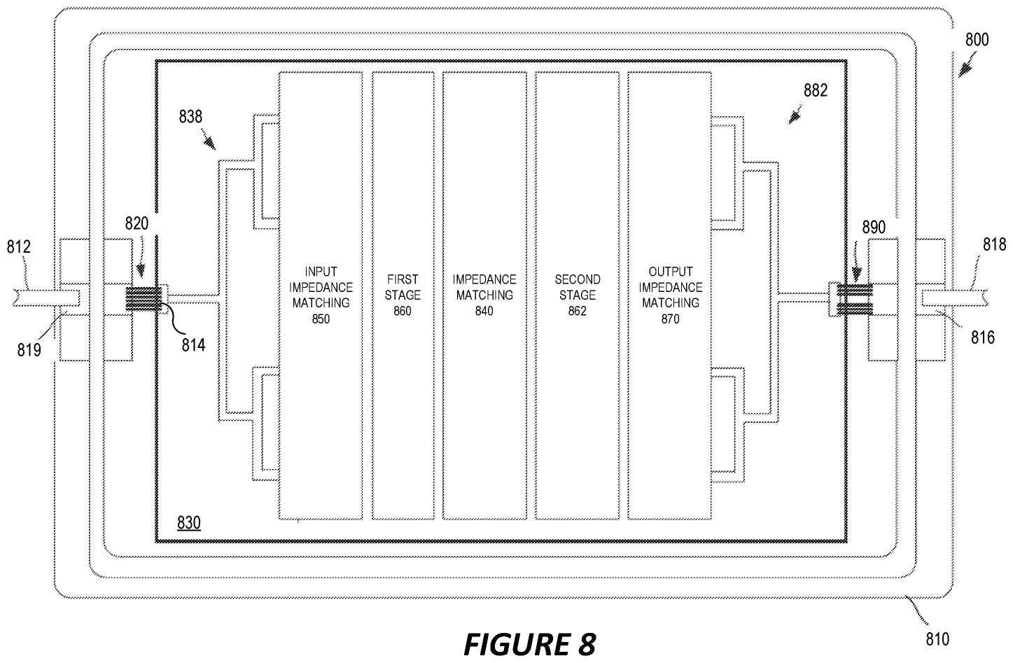

FIG. 8 is a plan view of a MMIC RF power amplifier 800 according to embodiments of the present inventive concepts. As shown in FIG. 8, the MMIC RF power amplifier 800 includes an integrated circuit chip 830 that is contained within a package 810. The package 810 may comprise a protective housing that surrounds and protects the integrated circuit chip 830. The package 810 may be formed of, for example, a ceramic material.

The package 810 includes an input lead 812 and an output lead 818. The input lead 812 may be mounted to an input lead pad 814 by, for example, soldering. One or more input bond wires 820 may electrically connect the input lead pad 814 to an input bond pad on the integrated circuit chip 830. The integrated circuit chip 830 includes an input feed network 838, an input impedance matching network 850, a first RF power amplifier stage 860, an intermediate impedance matching network 840, a second RF power amplifier stage 862, an output impedance matching stage 870, and an output feed network 882.

The package 810 further includes an output lead 818 that is connected to an output lead pad 816 by, for example, soldering. One or more output bond wires 890 may electrically connect the output lead pad 816 to an output bond pad on the integrated circuit chip 830. The first RF power amplifier stage 860 and/or the second RF power amplifier stage 862 may be implemented using any of the RF power amplifiers according to embodiments of the present inventive concepts.

The RF power amplifiers according to embodiments of the present inventive concepts may be designed to operate in a wide variety of different frequency bands. In some embodiments, these RF power amplifier dies may be configured to operate in at least one of the 0.6-2.7 GHZ, 3.4-4.2 GHZ, 5.1-5.8 GHZ, 12-18 GHz, 18-27 GHZ, 27-40 GHz or 90-75 GHz frequency bands or sub-portions thereof. The techniques according to embodiments of the present inventive concepts may be particularly advantageous for RF power amplifiers that operate at frequencies of 10 GHz and higher.

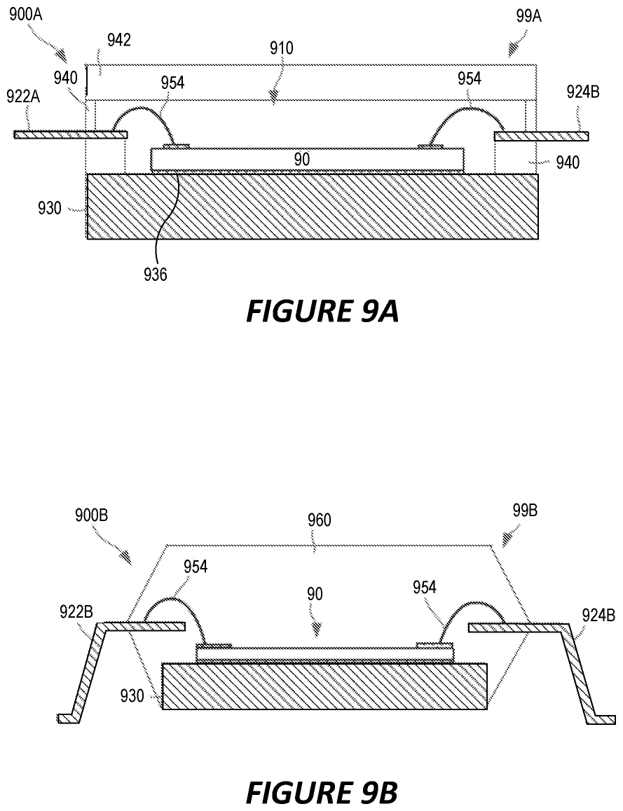

FIGS. 9A and 9B are schematic cross-sectional views illustrating several example transistor amplifier packages including RF power amplifier devices according to embodiments of the present inventive concepts.

FIG. 9A is a schematic side view of a packaged Group III nitride-based RF power amplifier 900A. As shown in FIG. 9A, packaged RF power amplifier 900A includes the RF power amplifier die 90 packaged in an open cavity package 910A. The package 910A includes metal gate leads 922A, metal drain leads 924A, a metal sub-mount 930, sidewalls 940 and a lid 942.

The sub-mount 930 may include materials configured to assist with the thermal management of the package 900A. For example, the sub-mount 930 may include copper and/or molybdenum. In some embodiments, the sub-mount 930 may be composed of multiple layers and/or contain vias/interconnects. In an example embodiment, the sub-mount 930 may be a multilayer copper/molybdenum/copper metal flange that comprises a core molybdenum layer with copper cladding layers on either major surface thereof. In some embodiments, the sub-mount 930 may include a metal heat sink that is part of a lead frame or metal slug. The sidewalls 940 and/or lid 942 may be formed of or include an insulating material in some embodiments. For example, the sidewalls 940 and/or lid 942 may be formed of or include ceramic materials.

In some embodiments, the sidewalls 940 and/or lid 942 may be formed of, for example, Al203. The lid 942 may be glued to the sidewalls 940 using an epoxy glue. The sidewalls 940 may be attached to the sub-mount 930 via, for example, braising. The gate lead 922A and the drain lead 924A may be configured to extend through the sidewalls 940, though embodiments of the present inventive concepts are not limited thereto.

The RF power amplifier die 90 is mounted on the upper surface of the metal sub-mount 930 in an air-filled cavity 912 defined by the metal sub-mount 930, the ceramic sidewalls 940 and the ceramic lid 942. The gate and drain terminals of RF power amplifier die 90 may be on the top side of the semiconductor layer structure 150, while the source terminal is on the bottom side of the semiconductor layer structure 150.

The gate lead 922A may be connected to the gate terminal of RF power amplifier die 90 by one or more bond wires 954. Similarly, the drain lead 924A may be connected to the drain terminal of RF power amplifier die 90 by one or more bond wires 954. The source terminal may be mounted on the metal sub-mount 930 using, for example, a conductive die attach material (not shown). The metal sub-mount 930 may provide the electrical connection to the source terminal 936 and may also serve as a heat dissipation structure that dissipates heat that is generated in the RF power amplifier die 90.

The heat is primarily generated in the upper portion of the RF power amplifier die 90 where relatively high current densities are generated. This heat may be transferred though from the semiconductor layer structure to the source terminal and then to the metal sub-mount 930.

FIG. 9B is a schematic side view of another packaged Group III nitride based RF power amplifier 900B. RF power amplifier 900B differs from RF power amplifier 900A in that it includes a different package 910B. The package 910B includes a metal sub-mount 930, as well as metal gate and drain leads 922B, 924B. RF power amplifier 900B also includes a plastic over mold 960 that at least partially surrounds the RF power amplifier die 90, the leads 922B, 924B, and the metal sub-mount 930.

Other components of RF power amplifier 900B may be the same as the like-numbered components of RF power amplifier 900A and hence further description thereof will be omitted. While embodiments of the present inventive concepts are described above with respect to gallium nitride based RF power amplifiers, it will be appreciated that embodiments of the inventive concepts are not limited thereto. For example, the transistors described above may also be used as power transistors in switching and other applications.

Embodiments of the present inventive concepts have been described above with reference to the accompanying drawings, in which embodiments of the inventive concepts are shown. The inventive concepts may, however, be embodied in many different forms and should not be construed as limited to the embodiments set forth herein. Rather, these embodiments are provided so that this disclosure will be thorough and complete, and will fully convey the scope of the inventive concepts to those skilled in the art. Like numbers refer to like elements throughout. In the specification and the figures, two-part reference numbers (i.e., two numbers separated by a dash, such as 100-1) may be used to identify like elements. When such two-part reference numbers are employed, the full reference numeral may be used to refer to a specific instance of the element, while the first part of the reference numeral may be used to refer to the elements collectively.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present inventive concepts. As used herein, the term “and/or” includes any and all combinations of one or more of the associated listed items. The terminology used herein is for the purpose of describing particular embodiments only and is not intended to be limiting of the inventive concepts. As used herein, the terms “comprises,” “comprising,” “includes” and/or “including” specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Relative terms such as “below” or “above” or “upper” or “lower” or “horizontal” or “lateral” or “vertical” may be used herein to describe a relationship of one element, layer or region to another element, layer or region as illustrated in the figures.

Although embodiments of the inventive concepts have been described in considerable detail with reference to certain configurations thereof, other versions are possible. The field plates and gates can also have many different shapes and can be connected to the source contact in many different ways. Accordingly, the spirit and scope of the inventive concepts should not be limited to the specific embodiments described above.

Claims:

1. A method of forming a semiconductor device structure, comprising:
patterning a surface of a semiconductor substrate, wherein the semiconductor substrate comprises a material having a thermal conductivity greater than about 50 W/m-K;
conformally forming a heteroepitaxial layer structure on the surface of the semiconductor substrate; and
forming a semiconductor device in the heteroepitaxial layer structure.

2. The method of claim 1, wherein patterning the surface of the semiconductor substrate comprises etching a plurality of features into the semiconductor substrate.

3. The method of claim 2, wherein the plurality of features comprise trenches, pits, ridges and/or pedestals in the surface of the semiconductor substrate.

4. The method of claim 2, wherein the presence of the features in the surface of the semiconductor substrate causes a surface area of an interface between the heteroepitaxial layer structure and the semiconductor substrate to be larger than it would be absent the features in the surface of the semiconductor substrate.

5. The method of claim 4, wherein the surface area of the interface between the semiconductor substrate and the heteroepitaxial layer structure is at least about 50% greater than a surface area of the interface would be without the features.

6. The method of claim 2, wherein the plurality of features have rectangular cross-sections.

7. The method of claim 2, wherein the plurality of features have U-shaped or V-shaped cross-sections.

8. The method of claim 2, wherein the plurality of features comprise trenches, and wherein the trenches extend in a direction corresponding to a direction of a flow of charge carriers during device operation.

9. The method of claim 1, wherein the substrate comprises silicon carbide, and wherein the heteroepitaxial layer structure comprises a gallium nitride based material.

10. The method of claim 1, wherein the semiconductor device comprises a high electron mobility transistor.

11. The method of claim 1, wherein patterning the surface of the substrate comprises:
forming an etch mask on the surface of the substrate;
forming a plurality of openings in the etch mask; and
anisotropically etching the surface of the substrate through the plurality of openings in the etch mask to form a plurality of recessed features in the surface of the substrate.

12. The method of claim 10, wherein anisotropically etching the surface of the substrate is performed using a reactive ion etch.

13. The method of claim 1, wherein the substrate comprises a material having a thermal conductivity greater than about 100 W/m-K.

14. A semiconductor device structure, comprising:
semiconductor substrate having a patterned surface, wherein the semiconductor substrate comprises a material having a thermal conductivity greater than about 50 W/m-K, and a heteroepitaxial layer structure conformally formed on the patterned surface of the semiconductor substrate; and
at least one metal contact on the heteroepitaxial layer structure.

15. The semiconductor device structure of claim 14, wherein the surface of the semiconductor substrate comprises a plurality of three-dimensional features in the semiconductor substrate.

16. The semiconductor device structure of claim 15, wherein the plurality of features comprise trenches, pits, ridges and/or pedestals in the surface of the semiconductor substrate.

17. The semiconductor device structure of claim 15, wherein the presence of the features in the surface of the semiconductor substrate causes a surface area of an interface between the heteroepitaxial layer structure and the semiconductor substrate to be larger than it would be absent the features in the surface of the semiconductor substrate.

18. The semiconductor device structure of claim 17, wherein the surface area of the interface between the semiconductor substrate and the heteroepitaxial layer structure is at least about 50% greater than a surface area of the interface would be without the features.

19. The semiconductor device structure of claim 15, wherein the plurality of features have rectangular cross-sections.

20. The semiconductor device structure of claim 15, wherein the plurality of features have a U-shaped or V-shaped cross-section.

21. The semiconductor device structure of claim 15, wherein the plurality of features comprise trenches, and wherein the trenches extend in a direction corresponding to a direction of a flow of charge carriers during device operation.

22. The semiconductor device structure of claim 14, wherein the substrate comprises silicon carbide, and wherein the heteroepitaxial layer structure comprises a gallium nitride based material.

23. The met semiconductor device structure of claim 14, wherein the semiconductor device comprises a high electron mobility transistor.

24. The semiconductor device structure of claim 14, wherein the substrate comprises a material having a thermal conductivity greater than about 100 W/m-K.
